(19) United States
(12) Patent Application Publication
(10) Pub. No.: US 2026/0348043 A1
(43) Pub. Date: Nov. 5, 2026

(54) Method for Controlled Silicon Nitride Crystallization

(71) Applicant: U.S. Department of Energy, Lemont, IL (US)

(72) Inventors: Christopher Bishop, Rio Rancho, NM (US); Khalid Hattar, Knoxville, TN (US); Carlos Chacon, Rio Rancho, NM (US); Thomas Friedman, Albuquerque, NM (US); Jennie Podlevsky, Albuquerque, NM (US); James Matthew Doyle Lane, Albuquerque, NM (US); Tesia Janicki, Albuquerque, NM (US)

(73) Assignee: U.S. Department of Energy, Lemont, IL (US)

(21) Appl. No.: 19/198,297

(22) Filed: May 5, 2025

Related U.S. Application Data
(60) Provisional application No. 63/647,725, filed on May 15, 2024.

(51) Int. Cl. C30B 1/02; B81C 1/00; C23C 16/34; C23C 16/56; C30B 29/38

(52) U.S. Cl. CPC C30B 1/023; B81C 1/0038; C23C 16/345; C23C 16/56; C30B 29/38; B81C 2201/0102; B81C 2201/0164; B81C 2201/0166; B81C 2201/0167; B81C 2201/0169; B81C 2201/017; B81C 2201/0171

(57) ABSTRACT

A method for controllably forming crystalline silicon nitride (SiN) for use with semiconductor devices is disclosed. Crystalline SiN has favorable optical, electrical, and mechanical properties when compared to amorphous SiN. The method converts a deposited amorphous SiN layer into crystalline SiN at desired locations. The controlled conversion employs a two-step process. In the first step stress is induced in desired portions of the amorphous SiN layer. In the second step, the stressed portions, and adjacent areas are subjected to laser illumination to implement the conversion process. Depending upon the size and complexity of the desired crystalline SiN feature, one of multiple ways of inducing the stress may be employed. The deposition and conversion process is compatible with standard complementary metal oxide semiconductor (CMOS) processes.

### STATEMENT OF GOVERNMENT SUPPORT

This invention was made with Government support under Contract No. DE-NA0003525 awarded by the United States Department of Energy/National Nuclear Security Administration. The U.S. Government has certain rights in the invention.

### BACKGROUND OF THE INVENTION

### Field of the Invention

The present invention relates to methods for controllably crystallizing silicon nitride and may be used for micro-electromechanical system (MEMS) or optical devices.

### Brief Description of the Related Art

As deposited, silicon nitride (SiN) is traditionally amorphous. For many applications, this amorphous state of the SiN is the preferred state. However, amorphous silicon nitride may randomly convert to crystalline SiN, which can destroy the functionality of the original device. In other instances, crystalline SiN may be desired over amorphous SiN due to its favorable optical, electrical, and/or mechanical properties.

Thus, the need exists for a way to controllable form crystalline SiN for those devices that will benefit from its inclusion.

### SUMMARY OF THE INVENTION

One aspect of the present invention relates to a way to controllably form crystalline SiN in devices to take advantage of its favorable optical, electrical, and/or mechanical properties. The process includes depositing an amorphous SiN layer and subsequently converting the amorphous SiN into crystalline SiN at desired locations. The controlled conversion typically employs a two-step process. In the first step stress is induced in the original amorphous SiN layer. In the second step, the stressed areas are subjected to laser illumination to complete the conversion process. Depending upon the size and complexity of the desired crystalline SiN feature, one of multiple ways of inducing the stress may be employed. Of note is that the deposition and conversion process is compatible with standard complementary metal oxide semiconductor (CMOS) processes.

In at least one embodiment of the invention, a process for forming crystalline silicon nitride (SiN) comprises steps of forming an amorphous SiN layer on a surface, forming one or more stressed regions in the SiN layer, and illuminating each stressed region with a laser beam, the laser beam converting the stressed regions into crystalline SiN.

In various embodiments, the amorphous SiN layer has a thickness between approximately 300 nm and 2 μm; the amorphous SiN layer is formed by a chemical vapor deposition (CVD) process; each of the stressed regions is formed by etching a corresponding recess in a surface of the amorphous SiN layer; a depth of each corresponding recess is between approximately 5 nm and a thickness of the amorphous SiN layer; each of the stressed regions is defined by placing a plurality of particles on a desired portion of a surface of the amorphous SiN layer; the particles include particles of copper (Cu), gold (Au), iron (Fe), and/or nickel (Ni); a size of the particles is at least 5 nm; each of the stressed regions is formed by an implant process in a surface of the amorphous SiN layer; and the implant process employs atoms or ions of hydrogen (H), helium (He), carbon (C), oxygen (O), aluminum (Al), silicon (Si), sulphur(S), chlorine (CI), chrome (Cr), manganese (Mn), Fe, Ni, Cu, germanium (Ge), arsenic (As), bromine (Br), palladium (Pd), silver (Ag), tin (Sn), iodine (I), tantalum (Ta), platinum (Pt), Au, and/or bismuth (Bi).

In various other embodiments, each of the stressed regions is formed by locally doping the amorphous SiN layer with a dopant; the dopant is phosphorous (P) and/or gallium (Ga); each of the stressed regions is formed by a nanoindentation process; each of the stressed regions is formed by depositing a doped poly-silicon layer below or over the amorphous SiN layer (the doped poly-silicon layer creating stress at the interface between the doped poly-silicon layer and the amorphous SiN layer); each of the stressed regions is formed by depositing a gallium nitride (GaN) layer below or over the amorphous SiN layer (the GaN layer creating stress at the interface between the GaN layer and the amorphous SiN layer); the laser beam has a wavelength of between approximately 100 nm and 2500 nm; the laser beam has a power density of between approximately 300 W/mm² and 500 W/mm²; and the laser beam has a spot size of approximately 100 μm.

Features from any of the disclosed embodiments may be used in combination with one another, without limitation. In addition, other features and advantages of the present disclosure will become apparent to those of ordinary skill in the art through consideration of the following detailed description and the accompanying drawings.

### BRIEF DESCRIPTION OF THE DRAWINGS

The drawings illustrate several embodiments of the invention, wherein identical reference numerals refer to identical or similar elements or features in different views or embodiments shown in the drawings. The drawings are not to scale and are intended only to illustrate the elements of various embodiments of the present invention.

FIGS. 1A-1D illustrate various methods of crystallizing silicon nitride in accordance with one or more embodiments of the present invention.

FIG. 2 illustrates a flow chart diagram of a crystalline SiN formation process in accordance with one or more embodiments of the present invention.

### DETAILED DESCRIPTION OF THE INVENTION

The terms “a” and “an” do not denote a limitation of quantity, but rather denote the presence of at least one of the referenced items. The term “or” means “and/or.” The terms “comprising,” “having,” “including,” and “containing” are to be construed as open-ended terms (i.e., meaning “including, but not limited to”).

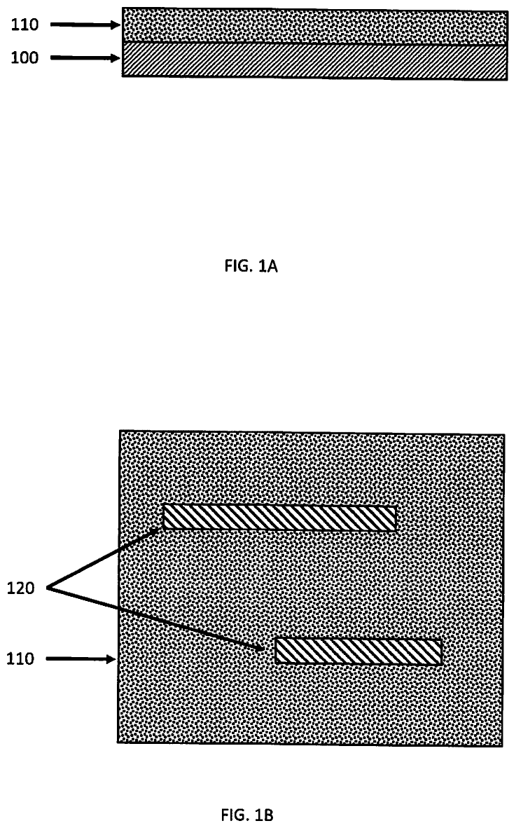

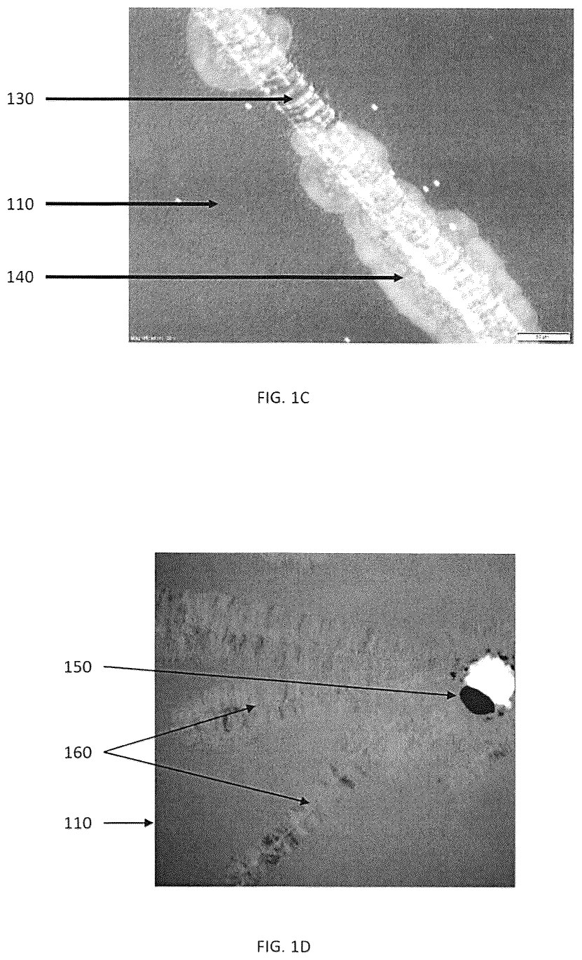

The following describes a process, with several variations, by which a crystalline silicon nitride (SiN) feature may be formed in accordance with one or more embodiments. As illustrated in FIG. 1A, an amorphous SiN layer 110 is formed on the surface of a device 100. The device 100 will typically not be complete at this point in the overall process. Thus, the following described process will typically be incorporated into a larger overall fabrication sequence. The amorphous SiN layer 110 may be formed by any suitable method, including, for example, chemical vapor deposition (CVD) or low-pressure CVD. Stress within the SiN layer 110 may be adjusted by changing the Si concentration during deposition of the SiN layer 110. The SiN layer 110 may have any suitable thickness, with thicknesses in the range of approximately 300 nm to 2 μm being typical for many devices. The SiN layer 110 is then subjected to a source of stress, which results in selected portions of the SiN layer 110 becoming stressed regions 120, as illustrated in plan view in FIG. 1B.

There are multiple ways of inducing the stressed regions 120. As a first example, the stressed regions 120 may be formed etching a recess 130 in the surface of the SiN layer 110. In this case, crystallized SiN regions 140 will ultimately form on either side of the recess 130, as illustrated in the micrograph of FIG. 1C. The depth of the recess 130 may be from a few nm to completely through the SiN layer 110. As a second example, metallic particles 150, for example, copper (Cu), gold (Au), iron (Fe), or nickel (Ni) particles having a size of at least a few nm, may be scattered on the surface of the SiN layer 110, with a single particle 150 illustrated in FIG. 1D. While FIG. 1D illustrates one of many widely scattered particles, the particles may completely blanket the SiN layer 110. Note that the particles 150, by themselves, do not induce the stressed regions 120. The particles 150, upon illumination by a laser in a later step of the process, serve as nucleation points for the crystallization of portions of the SiN layer 110. In particular, the particles 150 more readily absorb the laser and heat up faster, creating thermally stressed regions 160, in the form of dendrites. The approach using the particles 150 is the least geometrically precise way of inducing stressed regions 120, and thus is best used when larger crystallized SiN regions are desired. As a third example, an implant process may be used to create well-defined stressed regions, which may be used to create precisely placed and patterned crystallized SiN regions. These well-defined stressed regions may, for example, be used to form optical waveguides. The implant process may, for example, employ implanting atoms or ions of hydrogen (H), helium (He), carbon (C), oxygen (O), aluminum (Al), silicon (Si), sulphur(S), chlorine (CI), chrome (Cr), manganese (Mn), Fe, Ni, Cu, germanium (Ge), arsenic (As), bromine (Br), palladium (Pd), silver (Ag), tin (Sn), iodine (I), tantalum (Ta), platinum (Pt), Au, or bismuth (Bi). The implant process may, for example, use an energy of approximately 3 MeV and a dose time of approximately 10 seconds. Other embodiments may induce the stressed regions 120 by locally doping the SiN layer 110, with the larger (or smaller) dopant atoms creating localized stress. Such dopants may include, for example, phosphorous (P) or gallium (Ga). In some embodiments, this localized doping may be implemented by forming a doped poly-Si layer (not illustrated) either below or over the SiN layer 110, and patterning the doped poly-Si layer to thereby define the stressed regions 120. The poly-Si is doped with P, with the P subsequently diffusing to the interface with the SiN layer 110 and into the SiN layer 110, thereby creating the stressed regions 120. In other embodiments, a GaN layer (not illustrated) may be formed either below or over the SiN layer 110, with Ga from the GaN layer subsequently diffusing to the interface with the SiN layer 110 and into the SiN layer 110, thereby creating the stressed regions 120. Still other embodiments may induce localized stressed regions 120 using nanoindentation, that is, subjecting the desired stressed regions 120 to localized physical pressure. Yet other embodiments may employ a combination of two or more of these methods to induce the stressed regions 120.

After creation of the stressed regions 120, 160, they are illuminated with a laser to locally crystallize the SiN layer 110 outward from the stressed regions 120, 160. As noted above with respect to FIG. 1C, crystallized SiN regions 140 will form outward from the stressed regions on either side of the recess 130. With respect to the particles 150, the laser will cause crystallization of the SiN layer 110 outward from the individual particles 150, forming dendrites as illustrated in FIG. 1D. When subjected to a laser for long enough, the individual crystallized SiN regions around corresponding particles 150 will coalesce, resulting in a continuous crystallized SiN layer. Both processes tend to form polycrystalline SiN features.

By illuminating the well-defined stressed regions of the third approach with a laser that follows the same path as the well-defined stressed regions, single crystal SiN or large grain polycrystalline SiN features can be formed. This is especially advantageous for optical applications that preferably employ a single crystal SiN waveguide core, as this will minimize scattering loses in the waveguide. Further, as the amorphous SiN layer 110 has a lower index of refraction than the crystalline SiN waveguide core, one can, for example, form both the core and cladding portions of a waveguide from SiN.

The laser illumination process has several parameters that may be optimized for a given application. While a laser having any suitable wavelength, for example from the near infrared (NIR—700 nm to 2500 nm) to the ultraviolet (UV—100 nm to 400 nm) may be employed, a laser having a wavelength of 1064 nm has demonstrated crystallization. While any suitable power density may be employed, a power density of between approximately 300 to 500 W/mm² has demonstrated crystallization. One factor affecting the optimal power density is the thickness of the amorphous SiN layer, with thicker layers typically requiring a higher power density. A second factor affecting the optimal power density is the scan rate of the laser, with higher scan rates typically requiring a higher power density. Depending upon the spot size of the laser, it may need to be scanned over the stressed regions 120, 160 to promote crystallization of the entire stressed regions 120, 160. In these cases, any suitable scan rate may be employed. While any suitable spot size may be employed, a spot size of approximately 100 μm has demonstrated crystallization. A larger spot size is preferable for larger conversions areas, while a smaller spot size is preferable for small/narrow applications, such as waveguides. From a time efficiency standpoint, it is preferrable to illuminate only the stressed regions and the immediately adjacent areas, however, the entire surface of the device (and thus the amorphous SiN) may be scanned.

In some embodiments, the laser-based crystallization process is optionally followed by an etch that removes the amorphous portions of the SiN layer 110 at a faster rate than the crystalline portions of the SiN layer 110. The result is a device with selective areas of crystalline SiN on the surface of the device. In other embodiments, a conformal layer may be formed on the remaining portions of crystalline SiN. Returning to optical devices, if the crystalline SiN region is a waveguide core, a silicon dioxide (SiO₂) conformal layer may be used to form part of the cladding for the overall waveguide.

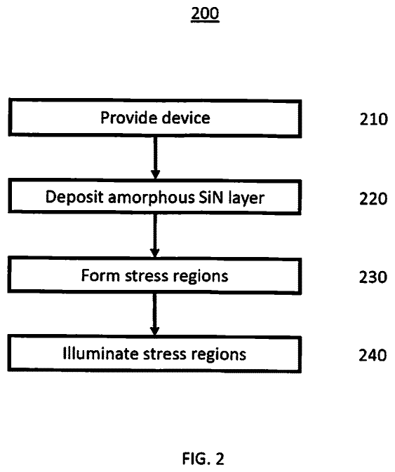

FIG. 2 illustrates a flow chart of the crystalline SiN formation process 200. In step 210, the underlying device is provided. In step 220, an amorphous SiN layer is deposited on the underlying device. In step 230, one or more stress regions are formed in the amorphous SiN layer. In step 240, the one or more stress regions are illuminated by a laser, thereby converting the stressed and illuminated regions of amorphous SiN to crystalline SiN.

As noted above crystalline SiN has at least two distinctions over amorphous SiN. First, there is a difference in the index of refraction between crystalline and amorphous SiN, which has ready application to various optical devices. Second, there is a difference in the etch rate between crystalline and amorphous SiN. This has ready application where precision etching of SiN is desired.

A third difference between crystalline and amorphous SiN is their mechanical hardness, with crystalline SiN being harder. Incorporation of this increased mechanical hardness into micro-electromechanical system (MEMS) devices, for example on wear surfaces such as the teeth of gears or pivot points, may extend the life of such MEMS devices.

A fourth difference between crystalline and amorphous SiN is their electrical properties. While both crystalline and amorphous SiN are generally insulating, their dielectric constants are different with the dielectric constant of crystalline SiN being less than that of amorphous SiN. Note that in some cases crystalline SiN can be made conductive using dopants.

All publications, including but not limited to patents and patent applications, cited in this specification are herein incorporated by reference as though set forth in their entirety in the present application.

The invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method for forming crystalline silicon nitride (SiN), comprising the steps of:
a) depositing an amorphous SiN layer on a surface of a layer by a method selected from chemical vapor deposition (CVD) and low pressure CVD;
b) forming one or more regions in the SiN region at a selected depth underneath surface of the substrate;
c) subjecting one or more regions in SiN region to stress with a suitable process to form stressed regions;
d) illuminating each of the one or more stressed regions with a laser beam or heat, the laser beam converting the one or more stressed regions into crystalline SiN; and
e) recovering crystalline SiN.

2. The method of claim 1, wherein the amorphous SiN layer has a thickness of between approximately about 300 nm and about 2 μm.

3. The method of claim 1, wherein a suitable process to form one or more stressed regions is selected from a group consisting of;
a) etching a corresponding recess in a surface of the amorphous SiN layer;
b) depositing a plurality of metallic particles on a desired portion of the stressed region;
c) implanting process employing atoms or ions;
d) doping the region with dopants; and
e) nanoindentation process.

4. The method of claim 3, wherein each of the one or more stressed regions is formed by etching process wherein a depth of each corresponding recess in etching is between approximately about 5 nm and the thickness of the amorphous SiN layer.

5. The method of claim 3, wherein the plurality of particles in process (b) comprises one or more particles selected from a group consisting of copper (Cu), gold (Au), iron (Fe), and nickel (Ni).

6. The method of claim 5, wherein a size of each of the plurality of metallic particles is at least about 5 nm.

7. The method of claim 3, wherein each of the one or more stressed regions is formed by an implant process on a surface of the amorphous SiN layer, comprising:
providing a substrate, the substrate comprising a stressed layer at a selected depth underneath a surface of the substrate, the stressed layer being at the selected depth to define a substrate material to be removed above the selected depth, the stressed layer comprising an implant over the deposited layer of amorphous SiN.

8. The method of claim 7 wherein the implant comprises a plurality of atoms or ions from a group selected from hydrogen (H), helium (He), carbon (C), oxygen (O), aluminum (Al), silicon (Si), sulphur(S), chlorine (CI), chrome (Cr), manganese (Mn), Fe, Ni, Cu, germanium (Ge), arsenic (As), bromine (Br), palladium (Pd), silver (Ag), tin (Sn), iodine (I), tantalum (Ta), platinum (Pt), Au, and bismuth (Bi).

9. The method of claim 3, wherein each of the one or more stressed regions is formed by locally doping the amorphous SiN layer with a dopant; said dopant selected from a group consisting of phosphorous (P) and gallium (Ga).

10. The method of claim 3, wherein each of the one or more stressed regions is formed by a nanoindentation process.

11. The method of claim 3, wherein each of the one or more stressed regions is formed by depositing a doped poly-silicon layer below or over the amorphous SiN layer, the doped poly-silicon layer adapted to create stress at the interface between the doped poly-silicon layer and the amorphous SiN layer.

12. The method of claim 1, wherein each of the one or more stressed regions is formed by depositing a gallium nitride (GaN) layer below or over the amorphous SiN layer, the GaN layer adapted to create stress at the interface between the GaN layer and the amorphous SiN layer.

13. The method of claim 1, wherein the laser beam has a wavelength of between approximately about 100 nm and about 2500 nm.

14. The method of claim 1, wherein the laser beam has a power density of between approximately about 300 W/mm² and about 500W/mm² ; said laser beam having a spot size of approximately about 100 μm.

15. The method of claim 13, wherein after the laser-based crystallization, the method further comprises an etching process to remove amorphous portions of SiN layer.

16. The method of claim 3, wherein upon illumination by a laser in a later step, the method further comprises the step of formation of nucleation points for the crystallization of portions of the SiN layer.

17. The method of claim 3, further comprising designing nucleation process by selecting a specific region of substrate and growing the amorphous SiN at a controlled rate by a combination of laser wavelength, power, and time.

18. The method of claim 7, wherein the process employed is ion/impurity implantation, further comprising: a) building layers of amorphous SiN; b) growing amorphous SiN layer; c) preparing impurity by implant into the amorphous SiN; and d) activating using laser.

19. The method of fabricating MEMS device comprising employing crystallized SiN according to claim 1.

20. A crystalline SiN according to claim 1 comprising 100% purity.
